(19) United States
(12) Patent Application Publication
(10) Pub. No.: US 2009/0080136 A1
(43) Pub. Date: Mar. 26, 2009

(54) ELECTROSTATIC CHUCK MEMBER

(75) Inventors: Nobuyuki Nagayama, Nirasaki-shi (JP); Yoshio Harada, Akashi-shi (JP); Junichi Takeuchi, Kobe-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignees: TOKYO ELECTRON LIMITED, Tokyo (JP); TOCALO CO., LTD., Kobe-shi (JP)

(21) Appl. No.: 12/238,635

(22) Filed: Sep. 26, 2008

Related U.S. Application Data
(60) Provisional application No. 61/017,401, filed on Dec. 28, 2007.

(30) Foreign Application Priority Data
Sep. 26, 2007 (JP) 2007-248443

(51) Int. Cl. H01L 21/683

(52) U.S. Cl. 361/234

(57) ABSTRACT

An electrostatic chuck member comprises an electrode layer and an electric insulating layer, wherein a spray coating layer of an oxide of a Group 3A element in the Periodic Table is formed as an outermost layer of the member and a surface of the spray coating layer is rendered into a densified re-melting layer having an average surface roughness (Ra) Of 0.8-3.0 μm.

### CROSS-REFERENCE TO RELATED APPLICATIONS

This document claims priority to Japanese Patent Application Number 2007-248443, filed on Sep. 26, 2007 and U.S. Provisional Application No. 61/017,401, filed on Dec. 28, 2007, the entire contents of each of which are hereby incorporated by reference.

### BACKGROUND OF THE INVENTION

1. Field of the Invention

This invention relates to an electrostatic chuck member suitable for use in a production process of a silicon semiconductor, a compound semiconductor, a flat panel display such as a liquid crystal or the like, a hard disk, a saw filter or other electron device.

2. Description of the Related Art

Recently, treatments such as dry etching and the like in a production process for semiconductors or liquid crystals, particularly a semiconductor production process change from a wet process into a dry process under vacuum or in an atmosphere under a reduced pressure from viewpoints of automation and anti-pollution. In the treatment through the dry process, it is important to enhance a positioning accuracy of a substrate such as silicon wafer, glass plate or the like in the patterning. In order to satisfy such a demand, a vacuum chuck or a mechanical chuck has hitherto been adopted in the transfer of the substrate or the adsorption fixation thereof. However, the vacuum chuck is treated under vacuum, so that the pressure difference is small and the adsorption effect is less. Even if the adsorption is attained, an adsorbing portion becomes local and strain is caused in the substrate. Furthermore, the gas cooling cannot be carried out with the temperature rising in the treatment of the wafer, so that the vacuum chuck cannot be applied to the recent production process of high-performance semiconductors. On the other hand, the mechanical chuck becomes complicated in the structure and takes a long time in the maintenance and inspection thereof.

In order to avoid the above drawbacks of the conventional techniques, electrostatic chucks utilizing static electricity are recently developed and widely adopted. However, this technique has a problem that when the substrate is adsorbed and held by the electrostatic chuck, even after the applied voltage is stopped, charge retains between the substrate and the electrostatic chuck, so that the detaching of the substrate cannot be carried out unless the charge is completely removed.

As a countermeasure therefore, it has been attempted to improve an insulating dielectric material itself used in the electrostatic chuck. For example, there are the following proposals:
(1) a spray coating made by mixing titanium oxide represented by TiₙO₂ₙ₋₁ with aluminum oxide as a high insulating material (Patent Document 1);
(2) an application of a spray coating having an improved high-temperature responsibility by mixing nickel oxide with aluminum oxide (Patent Document 2);
(3) an electrostatic chuck member of four layer structure made by disposing high insulating oxide layers on both sides of a metal electrode (Patent Document 3), and so on.
   [Patent Document 1] JP-A-H09-069554
   [Patent Document 2] JP-A-H10-154596
   [Patent Document 3] JP-A-2001-203258

The conventional electrostatic chucks described in Patent Documents 1-3 have the following problems. That is, the electrostatic chucks having a high insulating layer of aluminum oxide or the like have developed their functions at early years of semiconductor device working. In the recent years more dense and fine workings with a high precision are required, however, the above electrostatic chucks are liable to be corroded at a portion of the high insulating layer through a gas of a halogen compound in an environment or ions excited by plasma, and hence fine particles generated due to the corroded product inversely cause environmental pollution.

### SUMMARY OF THE INVENTION

It is, therefore, an object of the invention to propose an electrostatic chuck member capable of solving the above problems of the conventional electrostatic chuck having the high insulating layer or the like, particularly a novel construction of a coating layer thereof.

The inventors have made various studies for solving the problems of the conventional electrostatic chucks having the high insulating layer, and found that an electrostatic chuck member having the following summary and construction according to the invention has an effect of effectively preventing chemical damage of a substrate or an insulating layer mainly through a Coulomb's force, and as a result the invention has been accomplished. Moreover, according to the invention, the effect of preventing the chemical damage of the substrate or the insulating layer may be produced by a Jensen-Rahbek effect.

That is, the invention is an electrostatic chuck member comprising an electrode layer and an electric insulating layer, characterized in that a spray coating layer of an oxide of a Group 3A element in the Periodic Table is formed as an outermost layer of the member and a surface of the spray coating layer is rendered into a densified re-melting layer having an average surface roughness (Ra) of 0.8-3.0 μm.

According to the above construction, a change of a surface contact area due to friction between a silicon wafer and a surface of the electrostatic chuck is controlled, and also a change of a cooling effect with a lapse of time becomes less and stable. Further, when the lower limit of the surface roughness is defined in the electrostatic chuck, there is an effect of preventing a problem when the spray coating layer of the electrostatic chuck is rendered into a mirrored state, or a problem of falling the cooling effect due to the formation of gaps between the wafer and the electrostatic chuck in the presence of fine foreign matters.

In the invention, the followings are more effective means:
(a) the densified re-melting layer has a maximum roughness (Ry) of 6-16 μm;
(b) the densified re-melting layer is a secondary recrystallization layer formed by secondarily transforming a primarily transformed oxide included in such a layer through a high energy irradiation treatment;
(c) the densified re-melting layer is a layer having a structure of a tetragonal system by secondarily transforming a porous layer including a crystal of a rhombic system through a high energy irradiation treatment;
(d) the densified re-melting layer has a thickness of not more than 100 μm; and
(e) the high energy irradiation treatment is ether an electron beam irradiation or a laser beam irradiation.

The invention has the following effects:
(1) According to the invention, there can be provided an electrostatic chuck member which is well durable to a chemical corrosion action of various halogen compounds and a damage (plasma erosion) due to various ions including a halogen element excited by plasma while maintaining adsorption function of a semiconductor such as Si wafer or the like and does not form a pollution source in a semiconductor-working environment as it is;
(2) The electrostatic chuck member according to the invention is large in the resisting force and excellent in the durability to plasma erosion action under corrosion environment alternately repeating an atmosphere containing a gas of a halogen compound and an atmosphere containing a hydrocarbon gas;
(3) The electrostatic chuck member according to the invention is not corroded even by an acid, an alkali and an organic solvent, so that it is excellent in the corrosion resistance without corroding with a high purity water of a cleaning agent used in the cleaning of a whole of a semiconductor working device, and also the cleaning treatment is easy and can be stably used over a long time of period, and hence it contributes to improve the production of semiconductor products;
(4) According to the invention, an excellent corrosion resistance is developed to chemical corrosion action of a halogen gas or a halogen compound, so that the formation of corrosion product resulting in a source of generating particles can be prevented;
(5) The electrostatic chuck member according to the invention is less in the formation of fine particles made from constitutional components of the coating when the member is subjected to a plasma etching work under the corrosion environment and does not bring about the environmental pollution. Therefore, it can produce semiconductor elements of a high quality and the like efficiently;
(6) According to the invention, the surface of the re-molten spray coating is smooth and has no large protrusion, so that it does not damage a silicon wafer even in the contact therewith. Also, it does not form damage powder associated with the damage, so that the stable contact state can be maintained over a long time of period. Therefore, semiconductor working conditions are constant, and products having a high precision and a high quality can be produced efficiently.
(7) According to the invention, the surface of the re-molten spray coating provides a stable contact face with the silicon wafer as compared with the mechanically polished face because the spraying particles are fused with each other and there is no falling of fine particles even in contact with the silicon wafer. Therefore, the cooling action conducted from a side of the spray coating toward the substrate is effectively and equally transferred to the silicon wafer, so that the scattering of the working conditions is small and products of a high quality are obtained efficiently.
(8) According to the invention, the effects as mentioned above are obtained, so that it is possible to enhance the etching effect and rate by increasing output of plasma, and hence it is attempted to improve the semiconductor production system as a whole by miniaturization and weight reduction of the devices.

### BRIEF DESCRIPTION OF THE DRAWINGS

The invention will be described with reference to the accompanying drawings wherein:

FIG. 1 is a schematically cross-sectional view of an electrostatic chuck member;

FIG. 2 is a partial section view of (a) a member having a spray coating layer formed on a substrate surface and (b) a member having a densified re-melting layer as an outermost layer, respectively;

FIG. 3 is an X-ray diffraction pattern of a secondary recrystallization layer produced when a spray coating (porous layer) is subjected to an electron beam irradiation treatment;

FIG. 4 is an X-ray diffraction pattern of Y₂O₃ spray coating before electron beam irradiation treatment;

FIG. 5 is an X-ray diffraction pattern after electron beam irradiation treatment; and

FIG. 6 is a microphotograph showing each surface of a densified re-melting layer and a spray coating layer in Example.

### DESCRIPTION OF THE PREFERRED EMBODIMENTS

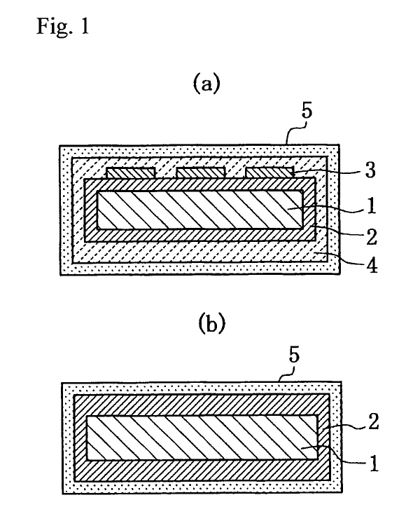

Typically, an electrostatic chuck member has a cross-sectional structure shown in FIGS. 1(a) and (b). In the figure, numeral 1 is a basic, electric-conductive substrate constituting an electrostatic chuck. On a surface of the substrate 1, an electric insulating layer 2 of aluminum oxide, boron nitride, aluminum nitride or a ceramic sintered body of sialon or the like is coated, and further a metallic electrode 3 of Mo, W or the like is attached onto a surface of the electric insulating layer 2. Furthermore, an electric insulating layer 4 is coated onto an overall outer surface including the electrode 3, and also a densified re-melting layer 5 as a construction inherent to the invention is coated onto an outer surface thereof.

On the other hand, FIG. 1(b) shows a structure that an electric insulating layer 2 of aluminum oxide or the like is disposed on a surface of an electrically conductive substrate 1 serving as an electrode and a spray coating layer is formed on an outer surface of the electric insulating layer 2 so as to totally cover it. Moreover, a wiring for flowing current (not shown) is connected to each substrate 1. The construction of these electrostatic chuck members is merely illustrated as an example, and is not intended as limitation thereof. According to the invention, there is a characteristic in the structure of a coating (densified re-melting layer) formed on the surface of the member.

The construction of the electrostatic chuck member according to the invention will be described in detail below.

Particularly, when the substrate 1 also serves as an electrode, it is required to have an electric conductivity and may be a metallic material such as Al, Al alloy, Ti, Ti alloy, Mg alloy, Ni-based alloy, chromium-based stainless steel or the like. Also, it is a carbonaceous material, concretely a non-metallic material such as graphite, sintered carbon or the like, and isotropic carbon or the like as disclosed in JP-B-H03-69845 is preferably used.

On the other hand, when the substrate does not serve as an electrode, there can be used ceramics such as quartz, glass, oxide, carbide, boride, silicide, nitride or a mixture thereof, inorganic material such as cermet made of the above ceramic and the above metal, plastics and so on in addition to the aforementioned materials. Also, as the substrate used in the invention may be used the aforementioned material provided on its surface with a metal plating (electroplating, galvanization, chemical plating) or a metal deposited film.

In the electric insulating layer 2 is preferably used a material having a high electric insulating property, concretely an electric resistivity of 10⁸-10¹³ Ωcm together with the above spray coating layer 5 coated thereon. Particularly, ceramics such as aluminum oxide, aluminum nitride, boron nitride, sialon and the like are preferable.

The electrostatic chuck member according to the invention is most effectively performed under such an environment that the member is subjected to a plasma etching work in a corrosive gas atmosphere. That is, the electrostatic chuck member used under such an environment is heavily corroded, and particularly when the member is used in an atmosphere of a gas containing fluorine or a fluorine compound (hereinafter referred to as “F-containing gas”) such as SF₆, CF₄, CHF₃, ClF₃, HF or the like, or in an atmosphere of a hydrocarbon gas such as C₂H₂, CH₄ or the like (hereinafter referred to as “CH-containing gas”) or in an atmosphere alternately repeating both the above atmospheres, it is heavily corroded.

In general, the F-containing gas atmosphere mainly includes fluorine or a fluorine compound and further may include oxygen (O₂). Particularly, fluorine is rich in the reactivity (strong in the corrosiveness) among halogen elements and has a characteristic that it reacts with not only a metal but also an oxide or a carbide to produce a corrosion product having a high vapor pressure. Therefore, the metal, oxide, carbide or the like existing in the F-containing gas atmosphere does not form a protection film for suppressing the progression of corrosion reaction on the surface, and hence the corrosion reaction is progressed indefinitely. As a result of the inventors' studies, elements belonging to Group 3A of the Periodic Table, i.e. Sc or Y and elements of Atomic Numbers 57-71 as well as oxides thereof indicate a relatively good corrosion resistance even under such an environment.

On the contrary, the CH-containing gas atmosphere has a characteristic that reduction reaction opposite to the oxidation reaction proceeding in the F-containing gas atmosphere occurs though CH itself has not a strong corrosiveness. For this end, the metal or metal compound indicating a relatively stable corrosion resistance in the F-containing gas atmosphere becomes weak in the chemical bonding force when being subsequently contacted with the CH-containing gas atmosphere. If the portion contacted with the CH-containing gas is again exposed to the F-containing gas atmosphere, an initially stable compound film is chemically destroyed and finally there is caused a phenomenon of promoting the corrosion reaction.

Particularly, in addition to the change of the above atmosphere gases, F and CH are ionized under an environment generating plasma to form atomic F and CH having a strong reactivity, and hence the corrosiveness and reducing property become stronger and the corrosion product is easily produced. The thus produced corrosion product vaporizes or forms fine particles in the plasma environment to considerably contaminate the interior of the plasma treating vessel. Therefore, the electrostatic chuck member according to the invention is effective as a corrosion countermeasure under the environment alternately repeating F-containing gas/CH-containing gas atmospheres, and serves to not only prevent the formation of the corrosion product but also control the formation of the particles. Especially, recent electrostatic chucks are subjected to an etching treatment utilizing strong plasma etching performance of F-containing gas and CH-containing gas for cleaning an adsorption face of Si wafer, so that the adsorption face of the Si wafer is also required to have a high resistance to plasma etching, and the invention is effective thereto.

Then, the inventors have first examined materials forming a film on the surface of the electrostatic chuck and showing good corrosion resistance and resistance to environment pollution even in the F-containing gas or CH-containing gas atmosphere. As a result, there is obtained a conclusion that it is effective to use an oxide of an element belonging to Group 3A of the Periodic Table as a coating material used in an outer layer (outer surface) of the electrostatic chuck member, particularly an outer surface of the electric insulating layer. Concretely, it has been confirmed that oxides of Sc, Y or lanthanides of Atomic Numbers 57-71 (La, Ce, Pr, Nb, Pm, Sm, Eu, Gd, Tb, Dy, Ho, Er, Tm, Yb, Lu), particularly rare earth oxides of La, Ce, Eu, Dy and Yb among the lanthanides are preferable. In the invention, these oxides may be used alone or in a combination of two or more, or as a composite oxide or an eutectic mixture. In the invention, the above metal oxides are noticed to be excellent in the resistance to halogen corrosion and the resistance to plasma erosion in the halogen gas as compared with the other oxide.

As seen from the above, the feature of the construction in the member according to the invention lies in that an oxide of Group 3A element in the Periodic Table showing excellent corrosion resistance and resistance to environment pollution under the corrosion environment is coated on to the surface of the substrate. As the coating means, it is preferable to adopt the following method.

That is, a spraying method is used as a method of forming a coating layer of a given thickness on a surface of a substrate. In the invention, therefore, an oxide of Group 3A element in the Periodic Table is formed as a spraying material powder having a particle size of 5-80 μm formed by pulverizing or granulating method and then sprayed onto the surface of the substrate by a predetermined method to form a spray coating layer of a porous film having a thickness of 50-2000 μm.

Moreover, as a method of spraying an oxide powder are preferable an atmospheric plasma spraying method and a low pressure plasma spraying method, but a water plasma spraying method, an explosive spraying method or the like may be applied in accordance with use conditions.

When the thickness of the spray coating layer obtained by spraying the oxide powder of Group 3A element in the Periodic Table is less than 50 μm, the performances as a coating under the above corrosion environment are not sufficient, while when it exceeds 2000 μm, the mutual bonding force among the spraying particles becomes weak and also stress generating in the film formation (which is mainly considered due to the shrinkage of volume by quenching particles) becomes large to easily break the film.

Moreover, the spray coating layer may be directly formed on an outer surface of an electric insulating layer located on a surface of the substrate, or an undercoat or the like may be formed and then a spray coating of an oxide may be formed on the undercoat.

As the undercoat, it is preferable to form a metallic coating such as Ni and an alloy thereof, Co and an alloy thereof, Al and an alloy thereof, Ti and an alloy thereof, Mo and an alloy thereof, W and an alloy thereof, Cr and an alloy thereof and so on through a spraying method or a deposition method, and the thickness is preferable to be about 50-500 μm. The undercoat plays a role for shielding the surface of the substrate from a corrosive environment to improve the corrosion resistance and improving the adhesiveness between the substrate and the porous spray coating layer. Therefore, when the thickness of the undercoat is less than 50 μm, the sufficient corrosion resistance is not obtained but also the uniform film formation is difficult, while when it exceeds 500 μm, the effect of corrosion resistance is saturated.

The spray coating layer made of the spray coating of the oxide of the Group 3A element in the Periodic Table has an average porosity of about 5-20% at as-sprayed state. Also, the porosity differs in accordance with the kind of the spraying method adopted such as a low pressure plasma spraying method, an atmospheric plasma spraying method and the like. A preferable range of the average porosity at the as-sprayed state is about 5-10%. When the porosity is less than 5%, residual stress stored in the coating becomes large and the resistance to thermal shock and adhesiveness are poor, while when it exceeds 10%, particularly 20%, the penetration of the corrosive gas into the interior of the coating is easy and the resistance to plasma erosion is poor.

The surface of the spray coating layer has an average roughness (Ra) of about 4-8 μm and a maximum roughness (Ry) of about 16-32 μm when the plasma spraying method is applied.

In the invention, the reason why the spray coating layer having the above porosity and roughness is formed is due to the fact that such a coating is excellent in the resistance to thermal shock and is cheaply obtained at a given thickness in a short time. Furthermore, this coating serves as a buffer for modifying thermal shock applied to the coating to mitigate such a thermal shock over the whole of the coating.

In a surface layer portion of the spray coating layer as a most characteristic construction of the invention, i.e. the porous spray coating of an oxide of Group 3A element in the Periodic Table, a new layer having a modified state of a portion of the outermost surface layer of the spray coating, i.e. a secondary recrystallized layer obtained by secondarily transforming the porous layer of the oxide of Group 3A element in the Periodic Table is formed.

Typically, in the metallic oxide of Group 3A element in the Periodic Table, for example, yttrium oxide (yttria: Y₂O₃), the crystal structure is a cubic belonging to a tetragonal system. As the powder of yttrium oxide (hereinafter referred to as yttria) is subjected to a plasma spraying, molten particles are rapid-quenched while flying toward the substrate at a high speed and deposited on the substrate with collision, during which the crystal structure is primarily transformed into a crystal form of a mixed crystal containing a monoclinic in addition to the cubic.

That is, the crystal form of the porous spray coating layer is constituted with a mixed crystal including a rhombic system and a tetragonal system by primary transformation through the rapid quenching in the spraying. On the contrary, the above secondary recrystallized layer is a layer wherein the crystal form of the mixed crystal by primary transformation is secondarily transformed into a crystal form of a tetragonal system.

In the invention, therefore, the spray coating layer of the oxide of Group 3A element in the Periodic Table made from the mixed crystal structure including mainly the primarily transformed crystal of rhombic system is subjected to a high energy irradiation treatment, whereby the spray deposited particles in the spray coating layer are heated at least above the melting point to again transform the layer (secondary transformation) to thereby turn back and crystallographically stabilize the crystal structure to the tetragonal system.

At the same time, thermal strain and mechanical strain stored in the spray deposited particle layer are released in the primary transformation by spraying to physically and chemically stabilize the properties, whereas the densification and smoothness of the layer associated with the melting are realized. As a result, the secondary recrystallized layer made of the oxide of Group 3A element in the Periodic Table changes into a dense and smooth layer as compared with the as-sprayed layer.

That is, the secondary recrystallized re-melting layer is a densified re-melting layer having a porosity of less than 5% (porosity of spray coating: 5-10%), preferably less than 2%, in which the surface roughness is 0.8-3.0 μm as an average roughness (Ra) (4-8 μm in the spray coating), 6-16 μm as a maximum roughness (Ry) (16-32 μm in the spray coating) and 3-14 μm as a 10-point average roughness (Rz) (14-24 μm in the spray coating). This changes into a layer structure considerably different from the above spray coating layer. Moreover, the control of the maximum roughness (Ry) is determined from a viewpoint of the resistance to environmental pollution considering, for example, the environment of the semiconductor processing apparatus. The reason is, the surface of the interior member in the vessel is cut out by plasma ions and electrons excited in the etching atmosphere to generate particles, which is significantly shown in the value of the maximum roughness (Ry) on the surface. That is, as the value becomes larger, the change of generating the particles increases.

In the electrostatic chuck member according to the invention, the densified re-melting layer formed on the surface of the substrate or on the metallic undercoat formed thereon is important to have which surface form, i.e. surface roughness, particularly roughness in a height direction. Even if the surface of the spray coating is re-melted, as particles not completely melted by a spraying source in the formation of the coating retain on the surface, large protrusion parts are formed on the surface even by the re-melting treatment. When such a surface contacts with the silicon wafer, flaws are caused in the wafer, while the contact between the surface of the spray coating and the wafer becomes insufficient and hence the cooling action of the gas usually conducted from the lower side of the coating becomes non-uniform. As a result, the plasma etching rate on the wafer is changed to lower the productivity of high-precision and high-quality products.

In order to change the surface of the spray coating to a predetermined surface roughness by re-melting, it is recommended to control irradiation power and irradiation number as an electron beam irradiation condition within the following condition ranges in accordance with the thickness of the spray coating (50-2000 μm):
Irradiation atmosphere: Ar gas of 10-0.005 Pa
Irradiation power: 1.0-10 KeV
Irradiation rate: 1-20 mm/s.
   As another method adopting irradiation conditions other than the above conditions, it is possible to conduct fine adjustment of the coating layer (secondary re-melting) by generating electron beams through an electron gun or by conducting the irradiation under a reduced pressure or in an inert gas under a reduced pressure.

As the high-energy irradiation method for forming the secondary recrystallized re-melting layer are preferable an electron beam irradiation treatment and a CO₂ or YAG laser irradiation treatment. Particularly, when the oxide of Group 3A element in the Periodic Table is subjected to the electron beam irradiation treatment, the temperature rises from the surface and finally reaches above the melting point to form a molten state. Such a melting phenomenon can be adjusted by making the electron beam irradiation power higher or increasing the irradiation number.

As the laser beam irradiation may be used a YAG laser utilizing a YAG crystal, a CO₂ gas laser using a gas as a medium, and so on. In the laser beam irradiation treatment, the following conditions are recommended:
Laser power: 0.1-10 kW
Laser beam area: 0.01-2500 mm²
Treating rate: 5-1000 mm/s

The layer subjected to the electron beam irradiation treatment or the laser beam irradiation treatment is transformed at a high temperature as mentioned above and forms secondary recrystallization precipitates in the cooling and changes into a physically and chemically stable crystal form, so that the modification of the coating proceeds at a unit of a crystal level. For instance, the Y₂O₃ coating formed by the atmospheric plasma spraying method is a mixed crystal including the rhombic system at the sprayed state and changes into substantially a cubic after the electron beam irradiation.

Then, the inventors have examined the state of the spray coating of the oxide of Group 3A element in the Periodic Table, and the state of the re-melting layer formed when the coating is subjected to the electron beam irradiation and the laser beam irradiation, respectively. Moreover, as the oxide of Group 3A tested in this examination, 7 oxide powders (average particle size: 10-50 μm) of Sc₂O₃, Y₂O₃, La₂O₃, CeO₂, Eu₂O₃, Dy₂0₃ and Yb₂O₃ are used. Then, a spray coating of 100 μm in thickness is formed by directly spraying each of these powders onto a one-side face of an aluminum specimen (size: width 50 mm×length 60 mm×thickness 8 mm) through atmospheric plasma spraying (APS) and low pressure plasma spraying (LPPS). Thereafter, the surface of these coatings is subjected to an electron beam irradiation treatment and a laser beam irradiation treatment, respectively. In Table 1, the test results are summarized.

Moreover, the reason why the examination is carried out on the spraying method for Group 3A element in the Periodic Table is due to the fact that the spraying results on lanthanide oxides of Atomic Numbers 57-71 are not reported up to the present and it is necessary to confirm whether or not there are effects on the formation of the coating suitable for the invention and the application of electron beam irradiation.

As seen from the examination results, the oxides to be tested are well melted even by a gas plasma heat source as shown by a melting point (2300-2600° C.) in Table 1 to form a relatively good coating though pores inherent to the oxide spray coating are existent. Also, when the surfaces of these coatings are subjected to the electron beam irradiation and the laser beam irradiation, it has been confirmed that all of these coatings change into dense and smooth surfaces as a whole while losing protrusions by the melting phenomenon. However, on the surface treated by the high-energy irradiation are observed the occurrence of fine cracks associated with the deposit shrinkage in the coagulation from the molten state. Moreover, many cracks have a width of less than 1 μm, so that they do not affect the surface roughness nor contact with the wafer, and hence they never cause troubles.

TABLE 1

| | | | | | Surface after high- | |
|---|---|---|---|---|---|---|
| | Oxide | | Formation of | | energy irradiation | |
| | Chemical | Melting | coating | | Electron | Laser |
| No. | formula | point (° C.) | APS | LPPS | beam | beam |
| 1 | Sc₂O₃ | 2423 | ◯ | ◯ | smooth- | smooth- |
| | | | | | dense | dense |
| 2 | Y₂O₃ | 2435 | ◯ | ◯ | smooth- | smooth- |
| | | | | | dense | dense |
| 3 | La₂O₃ | 2300 | ◯ | ◯ | smooth- | smooth- |
| | | | | | dense | dense |
| 4 | CeO₂ | 2600 | ◯ | ◯ | smooth- | smooth- |
| | | | | | dense | dense |
| 5 | Eu₂O₃ | 2330 | ◯ | ◯ | smooth- | smooth- |
| | | | | | dense | dense |
| 6 | Dy₂O₃ | 2931 | ◯ | ◯ | smooth- | smooth- |
| | | | | | dense | dense |
| 7 | Yb₂O₃ | 2437 | ◯ | ◯ | smooth- | smooth- |
| | | | | | dense | dense |

Note:
(1) As the melting point of the oxide, a highest temperature is shown because there is a scattering of temperature every literature.
(2) Formation of coating: APS = atmospheric plasma spraying method, LPPS = low pressure plasma spraying method

Among the specimens after the high energy irradiation treatment prepared in the above examination, the section of the Y₂O₃ spray coating before and after the electron beam irradiation treatment is observed by an optical microscope to measure a change of microstructure in the coating through the high energy irradiation treatment.

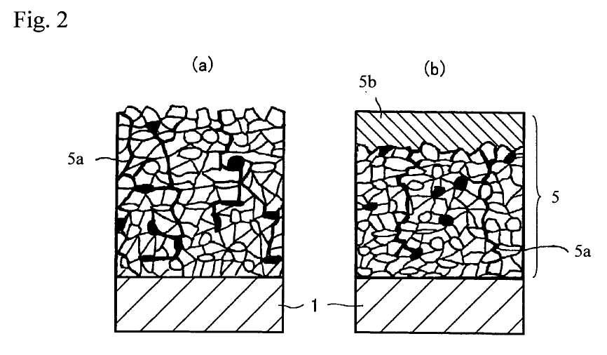

In FIG. 2, a change of microstructure in the vicinity of the surface of the densified re-melting layer 5b after the Y₂O₃ spray coating layer (porous film) is subjected to the electron beam irradiation treatment is schematically shown. In the non-irradiated specimen of FIG. 2(a), sprayed particles constituting the coating are existent independently and the surface roughness is large. On the other hand, as shown in FIG. 2(b), a new layer having a different microstructure is formed on the spray coating by the electron beam irradiation treatment, which is a dense layer being less in the space by mutually fusing the sprayed particles. Moreover, the coating having many pores inherent to the spray coating is existent below the dense layer produced by the electron beam irradiation, which is a layer having an excellent resistance to thermal shock.

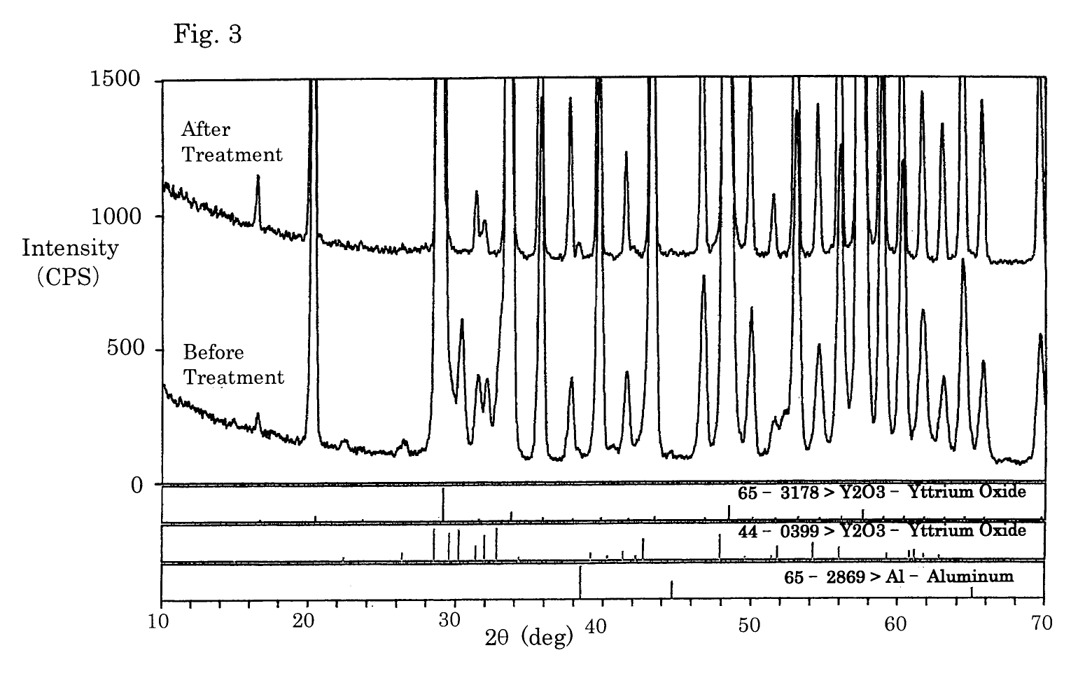

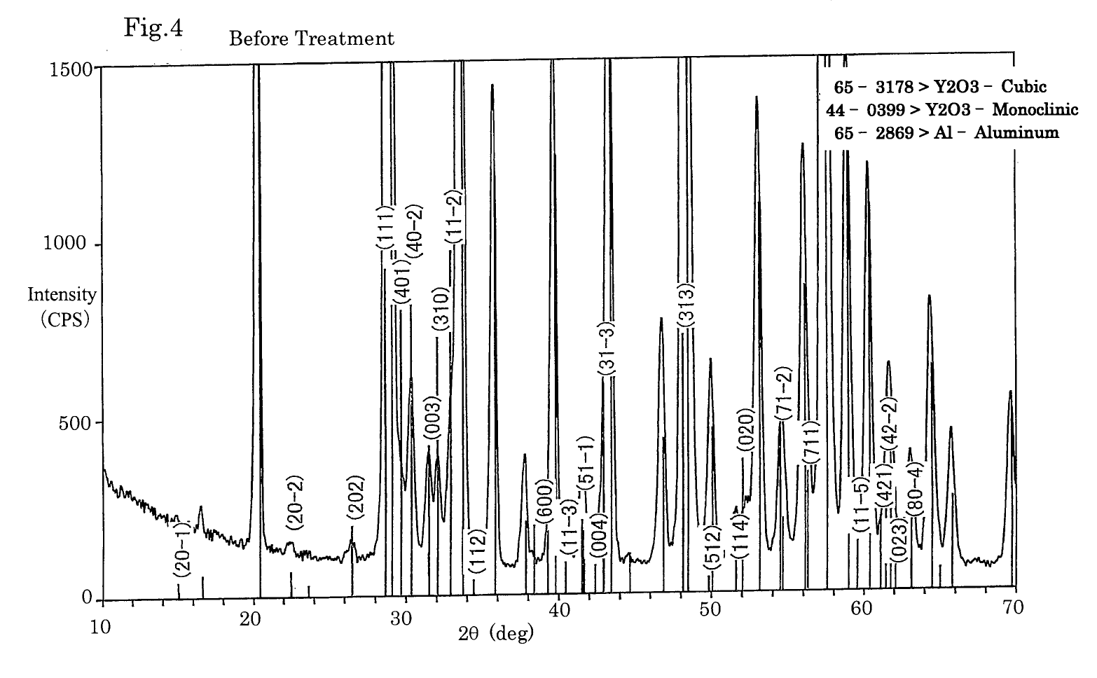

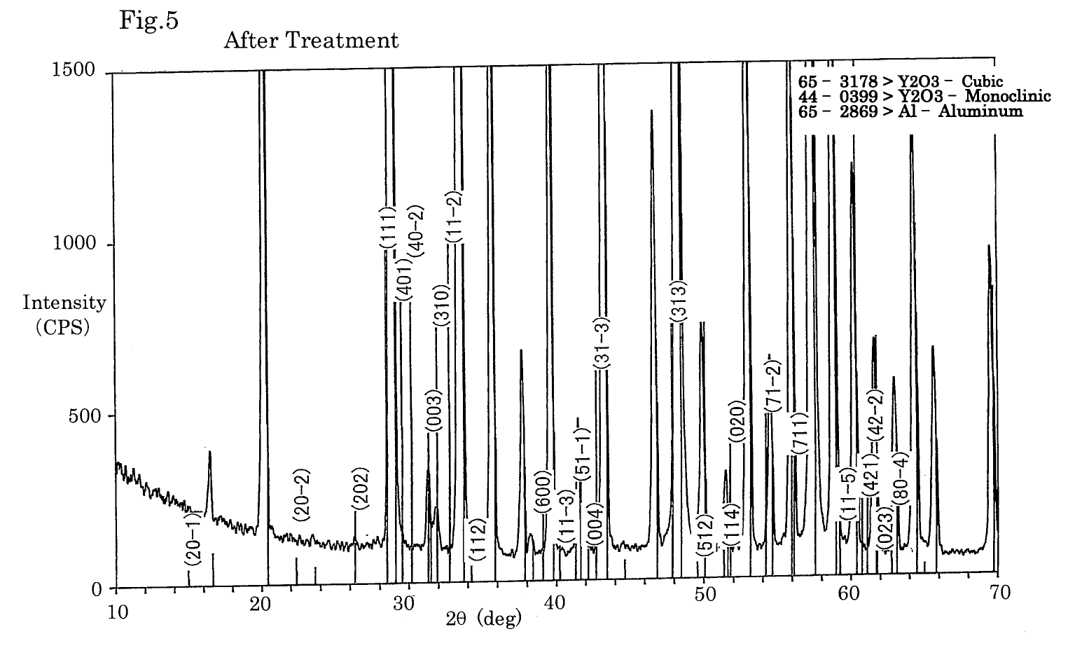

Next, the crystal structure is examined by measuring the Y₂O₃ spray coating layer of FIG. 2(a) and the secondary recrystallized, densified re-melting layer of FIG. 2(b) produced by the electron beam irradiation treatment under the following conditions through XRD. The results are shown in FIG. 3 as a XRD pattern before and after the electron beam irradiation treatment. Also, FIG. 4 is an X-ray diffraction chart by enlarging an ordinate before the treatment, and FIG. 5 is an X-ray diffraction chart by enlarging an ordinate after the treatment. As seen from FIG. 4, a peak showing the monoclinic is particularly observed within a range of 30-35°, so that the cubic and the monoclinic are mixed in the specimen before the treatment. On the other hand, as shown in FIG. 5, the secondary recrystallized layer after the electron beam irradiation treatment is confirmed to be only cubic because a peak showing Y2O3 particles becomes sharp and a peak of monoclinic is attenuated and plane index (202), (310) or the like is not confirmed. Moreover, this measurement is conducted by using an X-ray diffraction apparatus of RINT1500X made by Rigaku Denki-sha. X-ray diffraction conditions
Power: 40 kV
Scanning rate: 2°/min

EXAMPLE 1

An undercoat of 80 mass % Ni-20 mass % Cr (spray coating) is formed on a surface of Al substrate (size: 50 mm×50 mm×5 mm) by an atmospheric plasma spraying method and then powder of Y₂O₃ or CeO₂ is used to form a porous spray coating by an atmospheric plasma spraying method. Thereafter, the surface of the spray coating is subjected to two kinds of high energy irradiation treatments of electron beam irradiation and laser beam irradiation. Then, the surface of the thus obtained sample is subjected to a plasma etching under the following conditions. The particle number of the coating component flying by the etching treatment is measured to examine the resistance to plasma erosion and the resistance to environmental pollution. For the comparison, a time until 30 particles having a particle size of not less than 0.2 μm are adhered to a surface of a silicon wafer of 8 inches in diameter placed in a vessel is measured.
(1) Atmosphere Gas and Flow Rate Condition
   As F-containing gas, CHF₃/O₂/Ar=80/100/160 (flow rate cm³/min)
   As CH-containing gas, C₂H₂/Ar=80/100 (flow rate cm³/min)
(2) Plasma Irradiation Output
   High frequency power: 1300 W
   Pressure: 4 Pa
   Temperature: 60° C.
(3) Plasma Etching Test
   a. test in F-containing gas atmosphere
   b. test in CH-containing gas atmosphere
   c. test in an atmosphere alternately repeating F-containing gas atmosphere for 1 hour [symbol] CH-containing gas atmosphere for 1 hour

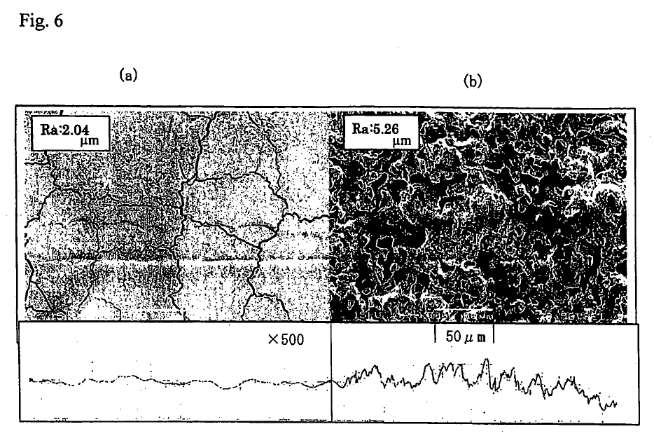

These test results are shown in Table 2. As seen from the results of this table, the test coatings suitable for the invention (No. 1 and No. 2) obtained by the electron beam irradiation or laser beam irradiation are confirmed to be a densified layer as shown in FIG. 6 wherein Ra before treatment=5.26 μm and Ra after treatment=2.04 μm. Also, the amount of particles generated by erosion exceeds 100 hours even if the etching is carried out while alternately repeating the CH-containing gas and the F-containing gas, and also the flying amount of the particles is very small and the resistance to plasma erosion is excellent.

On the contrary, in Comparative Example (No. 3) at as-sprayed state, the amount of particles generated exceeds the standard value in 35 hours. This is considered due to the fact that the chemical stability of the particles on the surface of the coating is damaged to lower the mutual bonding force between the particles and also the relatively stable fluoride as the coating component is easily flied by the etching action of plasma.

Moreover, the main component of the particles adhered to the surface of the silicon wafer is Y(Ce), F and C in the as-sprayed state (Comparative Example), whereas in Invention Example (secondary recrystallized layer) obtained by further subjecting the spray coating to the electron beam irradiation or laser beam irradiation, it is only F, C because the coating component is not substantially observed in the generated particles.

TABLE 2

| | | | | | Time until amount of | |
|---|---|---|---|---|---|---|
| | | | | | particles generated | |
| | | | | | exceeds an acceptable | |
| | | | | | value (h) | |
| | | | | | Alternately repeat of F- | |
| | Coating | Formation | Ra | | containing gas and CH- | |
| No. | material | of coating | (μm) | Ry | containing gas | Remarks |
| 1 | Y₂O₃ | spraying + | 2.04 | 8.5 | ≧100 | Invention |
| | | electron | | | | Example |
| | | beam | | | | |
| | | irradiation | | | | |
| 2 | CeO₂ | spraying + | 3.00 | 12.0 | ≧100 | Invention |
| | | laser | | | | Example |
| | | beam | | | | |
| | | irradiation | | | | |
| 3 | Y₂O₃ | only | 5.26 | 21.0 | ≦35 | Comparative |
| | | spraying | | | | Example |

Note:
(1) Coating of 150 μm in thickness is formed by an atmospheric plasma spraying method.
(2) Composition of F-containing gas: CHF₃/O₂/Ar = 80/100/160 (flow rate cm³/min)
(3) Composition of CH-containing gas: C₂H₂/Ar = 80/100 (flow rate cm³/min)
(4) Thickness of secondary recrystallized layer: after electron beam irradiation: 2-3 μm.

### EXAMPLE 2

A coating is formed by spraying a coating material as shown in Table 3 onto a surface of an Al substrate having a size of 50 mm×100 mm×5 mm. Thereafter, a part of the coatings is subjected to an electron beam irradiation treatment to form a secondary recrystallized layer suitable for the invention. Then, a test specimen having a size of 20 mm×20 mm×5 mm is cut out from the resulting mass and masked so as to expose the surface of the irradiation treated coating at an area of 10 mm×10 mm and subjected to a plasma irradiation under the following conditions to measure a damaged quantity due to plasma erosion by means of an electron microscope or the like.
(1) Atmosphere Gas and Flow Rate Condition
   CF₄/Ar/O₂=100/1000/10 ml (flow rate/min)
(2) Plasma Irradiation Output
   High frequency power: 1300 W
   Pressure: 133.3 Pa

The results are summarized in Table 3. As seen from the results of this table, all of anodized coating (No. 8), B4C spray coating (No. 9) and quartz (non-treated No. 10) in Comparative Examples are large in the damage quantity due to plasma erosion and are not practical.

On the contrary, the coatings (No. 1-7) each having a secondary recrystallized layer on the surface of the substrate show a high resistance to erosion because the element of Group 3A is used as a coating material and the densification treatment is carried out by the electron beam irradiation so as to adjust the average surface roughness (Ra) to a range of 0.8-3.0 μm. Particularly, it can be seen that the resistance force is more improved and the damaged quantity due to the plasma erosion is considerably reduced by the electron beam irradiation treatment.

TABLE 3

| | | | Damaged quantity due | | |
|---|---|---|---|---|---|
| | | | to plasma erosion (μm) | | |
| | Coating | Formation | | after electron | |
| No. | material | of coating | as-sprayed | beam irradiation | Remarks |
| 1 | Sc₂O₃ | spraying | 8.2 | not more than 0.1 | Invention |
| 2 | Y₂O₃ | spraying | 5.1 | not more than 0.2 | Example |
| 3 | La₂O₃ | spraying | 7.1 | not more than 0.2 | |
| 4 | CeO₂ | spraying | 10.5 | not more than 0.3 | |
| 5 | Eu₂O₃ | spraying | 9.1 | not more than 0.3 | |
| 6 | Dy₂O₃ | spraying | 8.8 | not more than 0.3 | |
| 7 | Yb₂O₃ | spraying | 11.1 | not more than 0.4 | |
| 8 | Al₂O₃ | anodizing | 40 | — | Comparative |
| 9 | B₄C | spraying | 28 | — | Example |
| 10 | quartz | — | 39 | — | |

Note:
(1) Atmospheric plasma spraying method
(2) Thickness of spray coating is 130 μm.
(3) Anodized coating is formed according to AA25 of JIS H8601.
(4) Thickness of densified re-melting layer after electron beam irradiation is 3-5 μm.

### EXAMPLE 3

In this example, the coating is formed in the same manner as in Example 2 and then the resistance to plasma erosion of the coating is examined before and after the electron beam irradiation treatment. As a test specimen, a coating of the following mixed oxide is directly formed on an Al substrate at a thickness of 200 μm by an atmospheric plasma spraying method.
(1) 95% Y₂O₃-5% Sc₂O₃
(2) 90% Y₂O₃-10% Ce₂O₃
(3) 90% Y₂O₃-10% Eu₂O₃

Moreover, the electron beam irradiation after the formation of the coating, atmosphere gas component, plasma spraying conditions and the like are the same as in Example 2.

In Table 4 are summarized the results on the damaged quantity due to plasma erosion. As seen from the results, the oxides of Group 3A elements in the Periodic Table under conditions suitable for the invention (i.e. formation of densified re-melting layer by subjecting the surface of the spray coating to the electron beam irradiation) are good in the resistance to plasma erosion even if these oxides are used at a mixed state as compared with Al₂O₃ (anodized coating) and B₄C coating of Comparative Examples shown in Table 3.

TABLE 4

| | | | Damaged quantity | Roughness |
|---|---|---|---|---|
| | | | due to plasma | of coating after |
| | | Formation | erosion after electron | irradiation |
| No. | Coating material | of coating | beam irradiation | (Ra) (μm) |
| 1 | 95%Y₂O₃—5%Sc₂O₃ | spraying | not more than 0.3 | 2.5 |
| 2 | 90%Y₂O₃—10%CeO₂ | spraying | not more than 0.2 | 2.0 |
| 3 | 90%Y₂O₃—10%Eu₂O₃ | spraying | not more than 0.3 | 2.2 |

Note
(1) Numeral in the column of coating material is shown by mass %.
(2) Atmospheric plasma spraying method
(3) Thickness of secondary recyrstallized layer after electron beam irradiation is 3-5 μm.

### INDUSTRIAL APPLICABILITY

The technique of the invention is used not only in the electrostatic chuck members and parts thereof used in the semiconductor processing apparatus but also as a surface treating technique of members in a plasma treating apparatus recently requiring more precise and skilled work. Also, the technique of the invention is applicable as a surface treating technique for members and parts such as deposhield, baffle plate, focus ring, upper-lower insulator rings, shield ring, bellows cover, electrode, solid dielectrics and the like in apparatuses using F-containing gas or CH-containing gas alone or in a semiconductor processing apparatus of plasma treatment under severe atmosphere alternately repeating both the gases. Furthermore, the invention is applicable as a surface treating technique of parts in a liquid crystal device production apparatus.

What is claimed is:

1. An electrostatic chuck member comprising an electrode layer and an electric insulating layer, characterized in that a spray coating layer of an oxide of a Group 3A element in the Periodic Table is formed as an outermost layer of the member and a surface of the spray coating layer is rendered into a densified re-melting layer having an average surface roughness (Ra) Of 0.8-3.0 μm.

2. An electrostatic chuck member according to claim 1, wherein the densified re-melting layer has a maximum roughness (Ry) of 6-16 μm.

3. An electrostatic chuck member according to claim 1, wherein the densified re-melting layer is a secondary recrystallization layer formed by secondarily transforming a primarily transformed oxide included in such a layer through a high energy irradiation treatment.

4. An electrostatic chuck member according to claim 1, wherein the densified re-melting layer is a layer having a structure of a tetragonal system by secondarily transforming a porous layer including a crystal of a rhombic system through a high energy irradiation treatment.

5. An electrostatic chuck member according to claim 1, wherein the densified re-melting layer has a thickness of not more than 100 μm.

6. An electrostatic chuck member according to claim 1, wherein the high energy irradiation treatment is ether an electron beam irradiation or a laser beam irradiation.
